(19) United States
(12) Patent Application Publication
(10) Pub. No.: US 2025/0138232 A1
(43) Pub. Date: May 1, 2025

(54) POLARIZING PLATE AND OPTICAL DISPLAY APPARATUS

(71) Applicant: SAMSUNG SDI CO., LTD., Yongin-si (KR)

(72) Inventors: Seon Gyeong JEONG, Suwon-si (KR); Seong Hoon LEE, Suwon-si (KR); Hyoung Tae LIM, Suwon-si (KR); Kyung Jun MIN, Suwon-si (KR); Se Hyun PARK, Suwon-si (KR); Jun Mo KOO, Suwon-si (KR); Beom Deok LEE, Suwon-si (KR)

(21) Appl. No.: 18/929,441

(22) Filed: Oct. 28, 2024

(30) Foreign Application Priority Data
Oct. 31, 2023 (KR) 10-2023-0148104

(51) Int. Cl. G02B 5/30; G02B 1/04; G02B 1/14; G02F 1/1335; H10K 59/80

(52) U.S. Cl. CPC G02B 5/305; G02B 1/04; G02B 1/14; G02B 5/3083; G02F 1/133531; H10K 59/8791

(57) ABSTRACT

A polarizing plate and an optical display apparatus are disclosed. The polarizing plate includes a polarizer; and a retardation layer stack formed on one surface of the polarizer, wherein the retardation layer stack includes a second retardation layer, a first adhesive layer, and a first retardation layer sequentially stacked from the one surface of the polarizer, the first adhesive layer has a modulus of 1×10⁵ Pa to 1×10⁶ Pa at 25° C., and the second retardation layer and the first adhesive layer satisfy Relation 1.

### CROSS-REFERENCE TO RELATED APPLICATION

The present application claims priority to and the benefit of Korean Patent Application No. 10-2023-0148104, filed on Oct. 31, 2023, in the Korean Intellectual Property Office, the entire disclosure of which is incorporated herein by reference.

### BACKGROUND

### 1. Field

The present disclosure relates to a polarizing plate and an optical display apparatus.

### 2. Description of the Related Art

A light emitting display device or a liquid crystal display, which includes an organic light emitting device (OLED), includes a polarizing plate to improve optical properties. The polarizing plate may include a single retardation layer or a retardation layer stack including two or more retardation layers. A polarizing plate including a retardation layer stack may ensure better improvement in optical properties than a polarizing plate including a single retardation layer. In order to ensure continuous improvement in optical properties (e.g., sustained optical performance), it is desirable that the polarizing plate have good durability and reliability.

The polarizing plate is typically disposed at an outermost periphery of the light emitting display device or the liquid crystal display. Accordingly, it is desirable for the polarizing plate to have good impact resistance such that retardation layers of the retardation layer stack does not suffer from fracture, cracking and/or depression if (e.g., when) the polarizing plate is exposed to external impact (e.g., forces).

Recently, there has been a growing interest in foldable optical displays. Therefore, the polarizing plate is desired or required to have excellent bending properties.

The background technique of the present disclosure is disclosed in Korean Patent Laid-open Publication No. 10-2013-0103595 and the like.

### SUMMARY DISCLOSURE

An aspect according to some embodiments of the present disclosure is directed toward a polarizing plate that has good durability and reliability even after being left at both high temperature and high humidity (hereinafter, high temperature/humidity) or at high temperature for a long period of time.

An aspect according to some embodiments of the present disclosure is directed toward a polarizing plate with high impact resistance.

An aspect according to some embodiments of the present disclosure is directed toward a polarizing plate with good bending properties.

An aspect according to some embodiments of the present disclosure is directed toward a polarizing plate that can provide good front contrast and can reduce lateral brightness in black mode to reduce light leakage and color variation at a lateral side.

Additional aspects will be set forth in part in the description which follows and, in part, will be apparent from the description, or may be learned by practice of the presented embodiments of the disclosure.

One aspect of the present disclosure relates to a polarizing plate.

According to one or more embodiments of the present disclosure, a polarizing plate includes: a polarizer having a first surface and a second surface facing the first surface; and a retardation layer stack on the first surface of the polarizer, wherein the retardation layer stack includes a second retardation layer, a first adhesive layer, and a first retardation layer sequentially stacked from the first surface of the polarizer, a storage modulus of the first adhesive layer at 25° C. is 1×10⁵ Pa to 1×10⁶ Pa, and the second retardation layer and the first adhesive layer satisfy Relation 1:

$$0.3 \leq T 2 / T 1 \leq 1. \qquad Relation 1$$

where T1 is a thickness of the first adhesive layer in unit of μm, and

T2 is a thickness of the second retardation layer in unit of μm.

Another aspect of the present disclosure relates to an optical display apparatus.

According to embodiments of the present disclosure, an optical display apparatus includes the polarizing plate as set forth above.

Embodiments of the present disclosure provide a polarizing plate that has good durability and reliability even after being left at high temperature/humidity or at high temperature for a long period of time.

Embodiments of the present disclosure provide a polarizing plate with high impact resistance.

Embodiments of the present disclosure provide a polarizing plate with good bending properties.

Embodiments of the present disclosure provide a polarizing plate that can provide good front contrast and can reduce lateral brightness in black mode to reduce light leakage and color variation at a lateral side.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings,

FIG. 1 is a cross-sectional view of a polarizing plate according to one or more embodiments of the present disclosure.

FIG. 2 is a cross-sectional view of a polarizing plate according to another embodiment of the present disclosure.

FIG. 3 is a cross-sectional view of a polarizing plate according to a further embodiment of the present disclosure.

FIG. 4 is a schematic diagram of impact resistance evaluation.

### DETAILED DESCRIPTION DISCLOSURE

Hereinafter, example embodiments of the present disclosure will be described in more detail with reference to the accompanying drawings. However, it should be understood that the present disclosure is not limited to the following embodiments and may be embodied in different ways. The following embodiments are provided to provide a thorough understanding of the disclosure to those skilled in the art. Although lengths, thicknesses or widths of various components may be exaggerated in the drawings for description of the disclosure, the present disclosure is not limited thereto. Like components will be denoted by like reference numerals throughout the drawings.

The terminology used herein is for the purpose of describing example embodiments and is not intended to limit the present disclosure. Herein, the singular forms “a”, “an”, and “the” are intended to include the plural forms as well, unless the context specifically indicates otherwise.

Herein, spatially relative terms, such as “upper” and “lower”, are defined with reference to the accompanying drawings. Thus, it will be understood that “upper surface” can be used interchangeably with “lower surface”. In addition, if (e.g., when) an element is referred to as being placed “on” another element, it may be directly placed on the other element, or intervening element(s) may be present. On the other hand, if (e.g., when) an element is referred to as being placed “directly on” another element, there are no intervening element(s) therebetween.

Herein, “in-plane retardation Re”, “out-of-plane retardation Rth”, and “degree of biaxiality NZ” are represented by Equations A, B and C, respectively:

$$R e = ( n x - ny ) \times d , \qquad ( A )$$

$$Rth = ( ( n x + ny ) / 2 - nz ) \times d , \qquad ( B )$$

$$NZ = ( nx - nz ) / ( nx - n y ) , \qquad ( C )$$

where nx, ny, and nz are the indexes of refraction of an optical device, as measured in the slow axis direction (nx), the fast axis direction (ny) and the thickness direction (nz) thereof at a measurement wavelength, respectively, and d is the thickness thereof (unit: nm).

In Equations A to C, the term “optical device” may refer to a first retardation layer, a second retardation layer, a protective layer, or a retardation layer stack. In Equations A to C, the term “measurement wavelength” may refer to a wavelength of 450 nm, 550 nm, or 650 nm.

Herein, the term “(meth)acryl” refers to acryl and/or methacryl.

Herein, the term “glass transition temperature” of a layer, such as the first adhesive layer, the first retardation layer, and the second retardation layer, may be measured by differential scanning calorimetry (DSC). For example, the glass transition temperature is a value measured on a specimen using Discovery (TA Instrument Inc.) by heating the specimen to 180° C. at a heating rate of 20° C./min in a nitrogen atmosphere (flow rate of 50 mL/min), cooling the specimen to −100° C., and heating the specimen again to 100° C. at a heating rate of 10° C./min, in which the specimen is prepared from 15 mg of each of the first adhesive layer, the first retardation layer, or the second retardation layer (on a 6 mm Al pan).

Herein, the term “modulus” of an adhesive layer, such as the first adhesive layer and the second adhesive layer, refers to the storage modulus. The storage modulus is a value measured on a specimen at 25° C. and at 60° C. while heating the specimen from 0° C. to 100° C. (heating rate: 10° C./min) using a storage modulus measurement instrument (Advanced Rheometry Expansion System (ARES), TA Instrument Inc.), in which the specimen is prepared by stacking the first adhesive layers or the second adhesive layers to form a laminate having a thickness of 500 μm and cutting the laminate into a circular shape with a diameter of 8 mm.

Herein, the term “moisture permeability” of a retardation layer refers to a value measured at 23° C. and at 99% to 100% relative humidity (RH). Moisture permeability may be measured on a specimen in a moisture permeability measurement instrument (PERMATRAN-W, Model 700), wherein the specimen is prepared by cutting the retardation layer to a size of 10 cm×10 cm (length×width). Herein, “moisture permeability” of a protective layer may also be measured in the same manner as the retardation layer.

Herein, wavelength dispersion values of in-plane retardation at wavelengths of 450 nm, 550 nm, and 650 nm are represented by Re(450)/Re(550), Re(550)/Re(550), and Re(650)/Re(550), respectively.

Herein, wavelength dispersion values of out-of-plane retardation at wavelengths of 450 nm, 550 nm, and 650 nm are represented by Rth(450)/Rth(550), Rth(550)/Rth(550), and Rth(650)/Rth(550), respectively.

As used herein to represent a specific numerical range, “X to Y” represents “greater than or equal to X and less than or equal to Y (X≤ and ≤Y)”.

According to one or more embodiments, a polarizing plate includes a polarizer; and a retardation layer stack formed on one surface (e.g., a first surface) of the polarizer, wherein the retardation layer stack includes a second retardation layer, a first adhesive layer, and a first retardation layer sequentially stacked from the one surface of the polarizer.

According to one or more embodiments, there is provided a polarizing plate that has good durability and reliability even after being left at high temperature/humidity or at high temperature for a long period of time. For example, after the polarizing plate is left at high temperature/humidity or at high temperature for a long period of time, the polarizing plate can prevent or substantially prevent retardation layers constituting the retardation layer stack, that is, the first retardation layer and the second retardation layer, from being separated from each other by a physical force. Herein, the term “physical force” refers to force exerted by a hand, e.g., forcing the first retardation layer and the second retardation layer to be separated from each other by hand.

According to one or more embodiments, there is provided a polarizing plate that has good impact resistance. For example, if (e.g., when) external impact is applied to the polarizing plate from a polarizer side, the polarizing plate can prevent or substantially prevent each of the retardation layers constituting the retardation layer stack, for example, the second retardation layer, from fracture, cracking, and/or depression (e.g., become indented). Herein, the term “external impact” may refer to impact, for example, exerted by dropping a certain object from a set or predetermined height onto the polarizing plate.

According to one or more embodiments, there is provided a polarizing plate that increases a front contrast ratio. In addition, the polarizing plate according to the embodiment also provides effects of reducing light leakage and color variation at a lateral side while ensuring good clarity on a black screen. Further, the polarizing plate according to the embodiment also provides good (e.g., wide) viewing angle.

As will be described in more detail below, the retardation layer stack may be disposed between the polarizer and an optical display panel. The polarizing plate reduces light leakage and color variation at a lateral side while securing good clarity on a black screen and good viewing angle.

In one or more embodiments, the polarizing plate can be used as a viewer-side polarizing plate or a light source-side polarizing plate in a transverse field liquid crystal optical display, for example, an in-plane switching (IPS) or fringe field switching (FFS) mode liquid crystal display. Here, “viewer-side polarizing plate” refers to a polarizing plate that emits light after receiving light emitted from a liquid crystal panel.

In another embodiment, the polarizing plate can be used as an anti-reflection polarizing plate in a light emitting device display, for example, an OLED and the like.

The polarizing plate according to one or more embodiments of the disclosure will be described in more detail below.

### Retardation Layer Stack

The retardation layer stack is disposed between the polarizer and the optical display panel.

The retardation layer stack may be stacked on a light exit surface of the polarizer with respect to internal light (in the case where the polarizing plate is a light source-side polarizing plate) or on a light incidence surface of the polarizer (in the case where the polarizing plate is a viewer-side polarizing plate). Herein, “internal light” may be light emitted from a backlight unit.

The retardation layer stack includes a second retardation layer, a first adhesive layer, and a first retardation layer sequentially stacked from the polarizer.

### First Adhesive Layer

In one or more embodiments, the first adhesive layer may be directly formed on each of the first retardation layer and the second retardation layer. Herein, “directly formed” refer to that no other adhesive layer and/or bonding layer is formed between the first retardation layer and the first adhesive layer and that no other adhesive layer and/or bonding layer is formed between the second retardation layer and the first adhesive layer.

The first adhesive layer has a storage modulus of 1×10⁵ Pa to 1×10⁶ Pa at 25° C., and the second retarding layer and the first adhesive layer satisfy the following Relation 1. The first adhesive layer satisfies both the above described range of modulus and Relation 1, which ensures that the polarizing plate has good durability and reliability by preventing or substantially preventing delamination of the first retardation layer and the second retardation layer even after being left at high temperature/humidity or at high temperature for a long period of time, and that the second retardation layer does not suffer from fracture, cracking and/or depression (e.g., become indented) even if (e.g., when) external impact is applied to the polarizing plate.

$$0.3 \leq T 2 / T 1 \leq 1. , \qquad ( 1 )$$

where T1 is a thickness of the first adhesive layer (unit: μm) and T2 is a thickness of the second retardation layer (unit: μm).

The first adhesive layer bonds the second retardation layer and the first retardation layer to each other and is disposed on a lower surface of the second retardation layer to absorb impact to the second retardation layer if (e.g., when) external impact is applied to the polarizer. The modulus of the first adhesive layer at 25° C. is set in consideration of the peel strength of the first adhesive layer with respect to the second adhesive layer and impact resistance of the polarizing plate.

If (e.g., when) the modulus of the first adhesive layer is less than 1×10⁵ Pa at 25° C., the polarizing plate can have poor impact resistance. If (e.g., when) the modulus of the first adhesive layer at 25° C. is greater than 1×10⁶ Pa, the polarizing plate can have poor impact resistance or low peel strength with respect to the second retardation layer, thereby providing poor durability and reliability. The above described range of modulus of the first adhesive layer at 25° C. may be desirable or advantageous for improving durability and reliability of the polarizing plate if (e.g., when) the second retardation layer is a non-liquid crystalline layer (e.g., the second retardation layer is not a liquid crystal layer and does not contain any liquid crystalline material), as described in more detail below. For example, the second retardation layer may be a cured product of a composition including at least one of a cellulose compound or a polystyrene compound.

In an embodiment, the first adhesive layer has a modulus at 25° C. of, for example, 1×10⁵ Pa, 2×10⁵ Pa, 3×10⁵ Pa, 4×10⁵ Pa, 5×10⁵ Pa, 6×10⁵ Pa, 7×10⁵ Pa, 8×10⁵ Pa, 9×10⁵ Pa, 1×10⁶ Pa, 2×10⁵ Pa to 9×10⁵ Pa, or 3×10⁵ Pa to 8×10⁵ Pa. Within these ranges, the polarizing plate can (e.g., easily) achieve the aforementioned effects and the first adhesive layer can be (e.g., easily) formed.

The modulus of the first adhesive layer at 25° C. may be realized by adjusting the type or kind of adhesive resin in a composition for the first adhesive layer. For example, if (e.g., when) the adhesive resin is a (meth)acrylic resin, the modulus of the first adhesive layer at 25° C. may be realized by adjusting the type or kind and/or content (e.g., amount) of each monomer in a monomer mixture forming the (meth)acrylic resin, and/or the type or kind and/or content (e.g., amount) of a curing agent, and/or the degree of curing.

Relation 1 is set in consideration of optical properties of the second retardation layer and durability, reliability and impact resistance of the polarizing plate. As will be described in more detail below, the second retardation layer is a +C (positive C) retardation layer and may have a set or predetermined thickness to provide a proper range of out-of-plane retardation. Relation 1 is set to ensure out-of-plane retardation of the second retardation layer that provides a +C retardation layer (e.g., +C retardation effect) while improving durability, reliability, and impact resistance of the polarizing plate.

If T2/T1 in Relation 1 is less than 0.3, the second retardation layer may not (or cannot) provide a target out-of-plane retardation and the first adhesive layer can have a relatively thick thickness, thereby providing a thick polarizing plate and poor impact resistance. If T2/T1 in Relation 1 is greater than 1.0, peel strength between the first adhesive layer and the second retardation layer can be reduced, whereby the polarizing plate can have poor properties in terms of durability, reliability and impact resistance.

In an embodiment, the polarizing plate has a value of 0.3 to 0.9, 0.4 to 0.9, 0.5 to 0.8, or 0.3 to 0.7, as calculated according to Relation 1. Within these ranges, the polarizing plate can (e.g., easily) achieve the aforementioned effects and the first adhesive layer can be (e.g., easily) formed.

In one or more embodiments, the first adhesive layer may have a thickness of 13 μm or less, for example, greater than 0 μm and less than or equal to 13 μm, for example, 0.1 μm, 0.5 μm, 1 μm, 2 μm, 3 μm, 4 μm, 5 μm, 6 μm, 7 μm, 8 μm, 9 μm, 10 μm, 11 μm, 12 μm, 13 μm, 2 μm to 13 μm, 3 μm to 12 μm, or 2 μm to 5 μm. Within these ranges, the polarizing plate can (e.g., easily) satisfy Relation 1.

In one or more embodiments, the second retardation layer may have a thickness of 10 μm or less, for example, 0.1 μm, 0.5 μm, 1 μm, 2 μm, 3 μm, 4 μm, 5 μm, 6 μm, 7 μm, 8 μm, 9 μm, 10 μm, greater than 0 μm and less than or equal to 10 μm, or 2 μm to 8 μm. Within these ranges, the polarizing plate can (e.g., easily) satisfy Relation 1 and achieve reduction in thickness of the retardation layer stack.

Relation 1 may be realized (e.g., satisfied) by adjusting the thicknesses of the first adhesive layer and the second retardation layer in the polarizing plate.

In one or more embodiments, the first adhesive layer may have a modulus at 60° C. of 6×10⁴ Pa to 8×10⁵ Pa, for example, 6×10⁴ Pa, 7×10⁴ Pa, 8×10⁴ Pa, 9×10⁴ Pa, 1×10⁵ Pa, 2×10⁵ Pa, 3×10⁵ Pa, 4×10⁵ Pa, 5×10⁵ Pa, 6×10⁵ Pa, 7×10⁵ Pa, 8×10⁵ Pa, or 8×10⁴ Pa to 6×10⁵ Pa, which is lower than the modulus of the first adhesive layer at 25° C. Within these ranges, the polarizing plate can ensure better durability and reliability after being left at high temperature/humidity or at high temperature for a long period of time.

In one or more embodiments, the first adhesive layer may have a modulus ratio (modulus at 25° C.: modulus at 60° C.) of 1.25:1 to 1.6:1. Within these ranges, the polarizing plate can ensure good durability and reliability over a wide range of temperatures.

In one or more embodiments, the first adhesive layer may have a glass transition temperature of −10° C. or less, for example, −60° C. to −10° C., or −50° C. to −15° C. Within these ranges, the first adhesive layer can (e.g., easily) reach the above described range of modulus.

In one or more embodiments, the first adhesive layer may be a pressure sensitive adhesive (PSA) layer.

The first adhesive layer may be formed of any suitable composition so long as the first adhesive layer can provide the above described range of modulus. For example, the first adhesive layer may be formed of a composition including at least one adhesive resin selected from among (meth)acrylic based, epoxy based, epoxy (meth)acrylic based, urethane based, urethane (meth)acrylic based, and silicone based resins. For example, the first adhesive layer may include a thermoset product of the composition and/or a photo-cured product of the composition.

In one or more embodiments, the first adhesive layer may include a thermal cured product of a composition including a (meth)acrylic based resin. The (meth)acrylic based resin can be (e.g., easily) available as a monomer and can facilitate formation of the adhesive layer. Hereinafter, the composition including a (meth)acrylic based resin will be described in more detail as an example.

The composition includes a (meth)acrylic based resin.

The (meth)acrylic based resin may include a (meth)acrylic copolymer of a monomer mixture including a (meth)acrylic monomer containing an alkyl group and a (meth)acrylic monomer containing a cross-linkable functional group.

The (meth)acrylic monomer containing an alkyl group may include a (meth)acrylic acid ester containing a straight or branched C₁ to C₂₀ alkyl group at an ester site thereof. For example, the (meth)acrylic monomer containing an alkyl group may include at least one selected from among methyl (meth)acrylate, ethyl (meth)acrylate, propyl (meth)acrylate, n-butyl (meth)acrylate, iso-butyl (meth)acrylate, pentyl (meth)acrylate, hexyl (meth)acrylate, heptyl (meth)acrylate, 2-ethylhexyl (meth)acrylate, octyl (meth)acrylate, iso-octyl (meth)acrylate, nonyl (meth)acrylate, decyl (meth)acrylate, and dodecyl (meth)acrylate, without being limited thereto.

The (meth)acrylic monomer containing a cross-linkable functional group may include at least one selected from among a (meth)acrylic monomer containing a hydroxyl group, a (meth)acrylic monomer containing a carboxylic acid group, a (meth)acrylic monomer containing an amino group, and a (meth)acrylic monomer containing an epoxy group.

The (meth)acrylic monomer containing a hydroxyl group may include a (meth)acrylic acid ester containing a C₁ to C₂₀ alkyl group having at least one hydroxyl group at an ester site thereof. For example, the (meth)acrylic monomer containing a hydroxyl group may include at least one selected from among 2-hydroxyethyl (meth)acrylate, 2-hydroxypropyl (meth)acrylate, 2-hydroxybutyl (meth)acrylate, 4-hydroxybutyl (meth)acrylate, and 6-hydroxyhexyl (meth)acrylate.

The (meth)acrylic monomer containing a carboxylic acid group may include (meth)acrylic acid and/or the like.

The (meth)acrylic monomer containing an amino group may include a (meth)acrylic acid ester containing a C₁ to C₂₀ alkyl group having a primary amine group (NH₂), a secondary amine group (NH) or a tertiary amine group (N) at an ester site thereof. For example, the (meth)acrylic monomer containing an amino group may include dimethylaminoethyl (meth)acrylate, diethylaminoethyl (meth)acrylate, and/or the like, without being limited thereto.

The (meth)acrylic monomer containing an epoxy group may include a (meth)acrylic acid ester containing a C₁ to C₂₀ alkyl group having an epoxy group at an ester site thereof. For example, the (meth)acrylic monomer containing an epoxy group may include glycidyl (meth)acrylate and/or the like, without being limited thereto.

In one or more embodiments, the monomer mixture may include from 60 wt % to 99 wt %, for example, 80 wt % to 95 wt %, of the (meth)acrylic monomer containing an alkyl group, and 1 wt % to 40 wt %, for example, 5 wt % to 20 wt %, of the (meth)acrylic monomer containing a cross-linkable functional group, based on a total 100 wt % of the monomer mixture. Within these ranges, the (meth)acrylic resin can be (e.g., easily) prepared and adhesion of the first retardation layer to the second retardation layer can be improved.

The monomer mixture may further include a comonomer copolymerizable with the (meth)acrylic monomer containing an alkyl group and/or the (meth)acrylic monomer containing a cross-linkable functional group.

The comonomer may include at least one selected from among a (meth)acrylic monomer containing an aromatic group, a (meth)acrylic monomer containing an alicyclic group, and a (meth)acrylic monomer containing a heterocyclic group. Each of the (meth)acrylic monomer containing an aromatic group, the (meth)acrylic monomer containing an alicyclic group, and the (meth)acrylic monomer containing a heterocyclic group may be of a suitable one (e.g., typical type known to those skilled in the art). The comonomer may be present in an amount of 30 wt % or less, for example, 0 to 30 wt %, in the monomer mixture, based on a total 100 wt % of the monomer mixture.

The (meth)acrylic resin may have a weight average molecular weight of 500,000 g/mol to 3,000,000 g/mol, for example, 1,000,000 g/mol to 2,500,000 g/mol. The “weight average molecular weight” may be obtained by gel permeation chromatography using a polystyrene standard.

The (meth)acrylic resin may be prepared through polymerization of the monomer mixture by any suitable method (e.g., typical method known to those skilled in the art). For example, the (meth)acrylic resin may be prepared by solution polymerization, suspension polymerization, solid polymerization, and/or the like.

The composition may further include a curing agent, for example, a thermal curing agent.

The curing agent can cure the (meth)acrylic resin to increase adhesion of the first adhesive layer. The curing agent may be selected and used depending on the cross-linkable functional group of the (meth)acrylic resin. For example, the curing agent may include at least one selected from among an isocyanate curing agent, a metal chelate curing agent, an aziridine curing agent, an epoxy curing agent, and a carbodiimide curing agent. In an embodiment, the curing agent is a mixture of an isocyanate curing agent and a metal chelate curing agent.

The isocyanate curing agent may include a bifunctional to hexafunctional isocyanate curing agent. For example, the isocyanate curing agent may include at least one aromatic isocyanate curing agent selected from among toluene diisocyanate, xylylene diisocyanate, halogenated toluene diisocyanate, phenylene diisocyanates including m-phenylene diisocyanate and the like, and tetramethyl-xylylene diisocyanate, at least one aliphatic isocyanate curing agent selected from among hexamethylene diisocyanate and pentamethylene diisocyanate, an alicyclic isocyanate curing agent, for example, cyclohexamethylene diisocyanate and the like, and/or an adduct thereof, for example, at least one of a polyol such as trimethylolpropane (TMP) and the aforementioned curing agents. For example, the isocyanate curing agent may include an aromatic isocyanate curing agent, an aliphatic isocyanate curing agents, an alicyclic isocyanate curing agent, an adduct thereof, or a combination thereof.

According to one or more embodiments, the isocyanate curing agent may be present in an amount of 0.01 to 10 parts by weight, for example, 0.1 to 5 parts by weight, relative to 100 parts by weight of the (meth)acrylic resin. Within these ranges, the composition can ensure the above described desirable effects.

The metal chelate curing agent may be any suitable metal chelate curing agent. For example, the metal chelate curing agent may include a metal, for example, aluminum, titanium, iron, copper, zinc, tin, titanium, nickel, antimony, magnesium, vanadium, chromium, zirconium, and/or the like. For example, the metal chelate curing agent may include at least one selected from among aluminum ethylacetoacetate diisopropylate, aluminum tris (ethyl acetoacetate), alkyl acetoacetate aluminum diisopropylate, aluminum isopropylate, mono-sec-butoxyaluminum diisopropylate, aluminum-sec-butyrate, aluminum ethylate, tetraisopropyl titanate, tetra-n-butyl titanate, butyl titanate dimer, titanium acetylacetonate, titanium octylene glycolate, titanium tetraacetylacetonate, titanium ethyl acetoacetate, polyhydroxy titanium stearate, and aluminum acetylacetonate.

According to one or more embodiments, the metal chelate curing agent may be present in an amount of 0.01 to 10 parts by weight, for example, 0.01 to 3 parts by weight, relative to 100 parts by weight of the (meth)acrylic resin. Within these ranges, the composition can (e.g., easily) realize the above described desirable effects.

According to one or more embodiments, the curing agent may be present in an amount of 0.01 to 10 parts by weight, for example, 0.1 to 5 parts by weight, relative to 100 parts by weight of the (meth)acrylic resin. Within these ranges, the composition can (e.g., easily) realize the above described desirable effects.

The composition may further include an additive. The additive may include at least one selected from among a silane coupling agent, an antistatic agent, a pigment, a dye, an ultraviolet absorber, a heat stabilizer, and an antioxidant. In one or more embodiments, the silane coupling agent may be present in an amount of 0.01 to 10 parts by weight, for example, 0.1 to 5 parts by weight, relative to 100 parts by weight of the (meth)acrylic resin. Within these ranges, the composition can (e.g., easily) realize the above described desirable effects.

In one or more embodiments, the modulus of the first adhesive layer can be realized by adjusting the type or kind and/or content (e.g., amount) of the monomer mixture for the (meth)acrylic resin, the type or kind and/or content (e.g., amount) of the curing agent, and/or the like.

The first adhesive layer may be prepared by heat curing in a suitable method (e.g., known to those skilled in the art). For example, the composition for the first adhesive layer may be prepared by depositing the composition to a set or predetermined thickness on a release film and drying the composition at a set or predetermined temperature, for example, 30° C. to 80° C., for 0.5 hours to 5 hours.

### First Retardation Layer

The first retardation layer is a +A (positive A) layer (nx>ny=nz). The first retardation layer may be applied to an IPS or FFS mode LCD display to facilitate enhancement of the contrast ratio and widening of the viewing angle while minimizing or reducing color variation, if (e.g., when) combined with the second retardation layer that is a +C layer.

The first retardation layer may have an Re of 100 nm to 160 nm at a wavelength of 550 nm. Within this range, if (e.g., when) combined with the second retardation layer, the first retardation layer may be applied to an IPS mode liquid crystal display to enhance contrast ratio and widen viewing angle while minimizing or reducing color variation. In an embodiment, the first retardation layer has an Re of 120 nm to 150 nm, for example, 120 nm to 130 nm.

The first retardation layer may have an Rth of 50 nm to 85 nm, for example, 50 nm to 80 nm, or 55 nm to 70 nm, at a wavelength of 550 nm. Within these ranges, the first retardation layer can (e.g., easily) achieve the above described Re range.

The first retardation layer may have an NZ of 0.9 to 1.1, for example, 0.95 to 1.05, or 1 to 1.02, at a wavelength of 550 nm. Within these ranges, the first retardation layer can (e.g., easily) achieve the above described Re range.

The first retardation layer may have a positive wavelength dispersion (Re(450)>Re(550)>Re(650)) or a flat wavelength dispersion (Re(450)=Re(550)=Re(650)).

In one or more embodiments, the first retardation layer may have a short wavelength dispersion (Re(450)/Re(550)) of in-plane retardation in the range of 0.9 to 1.1 and a long wavelength dispersion (Re(650)/Re(550)) of in-plane retardation in the range of 0.9 to 1.1. Within these ranges, the first retardation layer can suppress lateral light leakage while reducing brightness in black mode. In an embodiment, the first retardation layer has a short wavelength dispersion of in-plane retardation in the range of 1.001 to 1.009 and a long wavelength dispersion of in-plane retardation in the range of 0.98 to 1.0.

In one or more embodiments, the first retardation layer may have an Re of 100 nm to 165 nm, for example, 10⁵ nm to 163 nm, at a wavelength of 450 nm, and an Re of 95 nm to 155 nm, for example, 96 nm to 153 nm, at a wavelength of 650 nm. Within these ranges, the first retardation layer can (e.g., easily) achieve the short wavelength dispersion and the long wavelength dispersion within the above ranges.

The first retardation layer may have a total light transmittance of 90% or more, for example, 90% to 100%, and a haze of 0.3% or less, for example, 0% to 0.3%, or 0.1% to 0.3%. Within these ranges, the first retardation layer can be used in the retardation layer stack.

The first retardation layer may have a thickness of 70 μm or less, for example, greater than 0 μm and less than or equal to 70 μm, for example, 20 μm to 70 μm, or 20 μm to 50 μm. Within these ranges, the first retardation layer can be used in a polarizing plate.

The first retardation layer is a non-liquid crystalline film, which may include a stretched film formed of an optically clear resin. The non-liquid crystalline film may refer to a film that is not formed of at least one of a liquid crystal monomer, a liquid crystal oligomer, or a liquid crystal polymer, a film formed of a material that is not converted into a liquid crystal monomer, a liquid crystal oligomer, or a liquid crystal polymer by light irradiation and/or the like. That is, the first retardation layer is a non-liquid crystalline film and does not include any liquid crystal monomers, liquid crystal oligomers, and/or liquid crystal polymers, and further does not include any material that can be converted into a liquid crystal monomer, a liquid crystal oligomer, and/or a liquid crystal polymer by light irradiation and/or the like.

For example, the first retardation layer may be a film formed of at least one resin selected from among cellulose resins including triacetylcellulose and the like, polyester resins including polyethylene terephthalate (PET), polybutylene terephthalate, polyethylene naphthalate, polybutylene naphthalate, and the like, cyclic olefin polymer (COP) resins, cyclic olefin copolymer (COC) resins, polycarbonate resins, polyether sulfone resins, polysulfone resins, polyamide resins, polyimide resins, polyolefin resins, polyarylate resins, polyvinyl alcohol resins, polyvinyl chloride resins, polyvinylidene chloride resins, and acrylic resins.

In one or more embodiments, the first retardation layer includes a cyclic olefin polymer (COP) or cyclic olefin copolymer (COC) film. In one or more embodiments, the cyclic olefin polymer (COP) film may be applied to a polarizing plate in an IPS or FFS mode liquid crystal display to facilitate improvement in contrast ratio and viewing angle while improving color variation.

The first retardation layer may be a hydrophobic film. In one or more embodiments, the first retardation layer may include a film formed of a resin having positive intrinsic birefringence. For example, the first retardation layer may include at least one selected from among a cyclic olefin polymer (COP) film, a cyclic olefin polymer (COC) film, and a cyclic olefin polymer (COP) film.

The first retardation layer may have a moisture permeability of 1 g/m²/day or more, for example, 1 g/m²/day to 30 g/m²/day, or 1 g/m²/day to 10 g/m²/day. Within these ranges, the first retardation layer can facilitate improvement in durability of the polarizing plate at high temperature/humidity or at high temperature.

The first retardation layer may have a glass transition temperature of 130° C. or more, for example, 130° C. to 200° C. Within these ranges, the first retardation layer can facilitate improvement in durability of the polarizing plate at high temperature/humidity or at high temperature.

The first retardation layer may be a film prepared by uniaxial stretching of an unstretched film for the first retardation layer in the machine direction (MD) or transverse direction (TD) or by uniaxial stretching of the unstretched film in an oblique direction to the MD. In an embodiment, the first retardation layer is a film prepared by MD uniaxial stretching of the unstretched film for the first retardation layer. Stretching conditions, such as a stretch ratio, a stretching temperature, a stretching method, and the like, may be adjusted to provide the above described range of Re at a wavelength of 550 nm. The unstretched film for the first retardation layer may be prepared through melt extrusion or solvent casting of the composition for the first retardation layer, without being limited thereto. Each of melt extrusion and solvent casting may be performed under a suitable condition (e.g., known to those skilled in the art).

The first retardation layer has a slow axis and a fast axis in an in-plane direction thereof, in which the slow axis of the first retardation layer may be substantially parallel to a light absorption axis of the polarizer. For example, assuming that the light absorption axis of the polarizer is 0°, the slow axis of the first retardation layer may be tilted at an angle of −5° to 5° thereto. In an embodiment, the slow axis of the first retardation layer is tilted at an angle of −0.5° to 0.5°, or −0.1° to 0.1° to the light absorption axis of the polarizer. Within these ranges, contrast ratio can be (e.g., easily) enhanced, viewing angle can be widened and color variation can be reduced or minimized.

### Second Retardation Layer

The second retardation layer is a +C layer (nz>nx≈ny). The second retardation layer may be applied to an IPS or FFS mode LCD display to facilitate enhancement of contrast ratio and widening of viewing angle while minimizing or reducing color variation, if (e.g., when) combined with the first retardation layer that is the +A layer

The second retardation layer may have an Rth of −110 nm to −50 nm at a wavelength of 550 nm. Within this range, the second retardation layer may be applied to a liquid crystal display to enhance the contrast ratio and widen the viewing angle while minimizing or reducing color variation. In an embodiment, the second retardation layer has an Rth of −110 nm to −60 nm, for example, −110 nm to −75 nm, at a wavelength of 550 nm.

The second retardation layer may have an Re of 10 nm or less, for example, 0 nm to 10 nm, at a wavelength of 550 nm. Within these ranges, the second retardation layer can (e.g., easily) achieve the above described range of Rth.

The second retardation layer may have positive wavelength dispersion or flat wavelength dispersion for both Re and Rth. In one or more embodiments, the second retardation layer may satisfy the following Relations 2 and 3. In these cases, the contrast ratio can be enhanced (e.g., easily) and the viewing angle can be widened while the color variation can be minimized or reduced.

$$1. \leq Re 2 ( 4 \; 50 ) / Re 2 ( 550 ) \leq 1.1 \qquad ( 2 )$$

$$1. \leq Rth 2 ( 4 \; 50 ) / Rth 2 ( 550 ) \leq 1.1 \qquad ( 3 )$$

where Re2(450) and Re2(550) are in-plane retardations of the second retardation layer at wavelengths of 450 nm and 550 nm, respectively (unit: nm), and

Rth2(450) and Rth2(550) are out-of-plane retardations of the second retardation layer at wavelengths of 450 nm and 550 nm, respectively (unit: nm).

The second retardation layer may have a total light transmittance of 90% or more, for example, 90% to 100%, and a haze of 1% or less, for example, 0% to 0.8%, or 0.1% to 0.7%. Within these ranges, the second retardation layer can be used in the retardation layer stack.

The second retardation layer may have a thickness of 10 μm or less, for example, greater than 0 μm and less than or equal to 10 μm, for example, 2 μm to 8 μm. Within these ranges, the second retardation layer can ensure reduction in thickness of the retardation layer stack.

The second retardation layer has a lower index of refraction than the first retardation layer and may have an index of refraction of 1 to 2, for example, 1.4 to 1.6, or 1.5 to 1.6.

1 The second retardation layer may have a moisture permeability of 1 g/m²/day or more, for example, 1 g/m²/day to 50 g/m²/day. Within these ranges, the second retardation layer can facilitate improvement in durability of the polarizing plate at high temperature/humidity or at high temperature.

The second retardation layer may have a glass transition temperature of 130° C. or more, for example, 130° C. to 200° C. Within these ranges, the second retardation layer can facilitate improvement in durability of the polarizing plate at high temperature/humidity or at high temperature.

The second retardation layer may be formed of a different material than the first retardation layer and may be formed of a hydrophobic material, which has different birefringence than that of the first retardation layer and has negative intrinsic birefringence.

The second retardation layer may be a non-liquid crystal layer. That is, the second retardation layer is a non-liquid crystal film and does not include any liquid crystal monomers, liquid crystal oligomers, and/or liquid crystal polymers, and further does not include any material that can be converted into a liquid crystal monomer, a liquid crystal oligomer, and/or a liquid crystal polymer by light irradiation and/or the like. With this structure, the polarizing plate can exhibit further improved durability after being left at high temperature/humidity or at high temperature for a long period of time.

The second retardation layer may include, as a main component, at least one of a cellulose compound or a polystyrene compound. The “compound” may refer to a polymer and/or an oligomer. In one or more embodiments, each of the cellulosic compound and the polystyrene compound may further contain a halogen (e.g., as a substituent). The halogen may include fluorine, chlorine, iodine or bromine. In one embodiment, each of the cellulosic compound and the polystyrene compound may further contain fluorine. Herein, “major component” refers to a component that is present in an amount of 90 wt % or more, for example, 95 wt % or more, in the second retardation layer, based on a total 100 wt % of the second retardation layer.

A resin having negative intrinsic birefringence may include a polymer having negative intrinsic birefringence. The polymer having negative intrinsic birefringence may include at least one selected from among, for example, a homopolymer of styrene or a styrene derivative, a polystyrene polymer including a copolymer of styrene or a styrene derivative and a comonomer, a polyacrylonitrile polymer, a poly (methyl methacrylate) copolymer, and a cellulose copolymer including a cellulose ester, a cellulose ether, and/or the like. The comonomer may include at least one selected from among acrylonitrile, maleic anhydride, methyl methacrylate, and butadiene. For example, the second retardation layer may include at least one of a polystyrene copolymer or a cellulose copolymer. In an embodiment, the second retardation layer may include a polystyrene copolymer.

In one or more embodiments, the cellulose copolymer may include a repeat unit represented by Formula 1. The cellulose copolymer may include a cellulose ester polymer including one or more units in which at least some of the hydrogen atoms of the hydroxyl (OH) groups (e.g., a C₂ hydroxyl group, a C₃ hydroxyl group or a C₆ hydroxyl group shown in Formula 1) of a sugar monomer constituting the cellulose are substituted with an acyl group. Here, the acyl group may be substituted or unsubstituted.

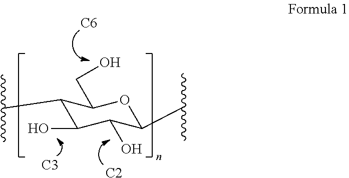

where n is an integer of 1 or more.

The polystyrene compound may include a moiety represented by Formula 2.

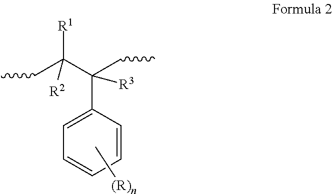

where [symbol] is a linking site of an element;

R¹, R² and R³ are each independently a hydrogen atom, an alkyl group, a substituted alkyl group, or a halogen;

R in a number of n are each independently an alkyl group, a substituted alkyl group, a halogen, a hydroxyl group, a carboxyl group, a nitro group, an alkoxy group, an amino group, a sulfonate group, a phosphate group, an acyl group, an acyloxy group, a phenyl group, an alkoxycarbonyl group, or a cyano group,

at least one of R¹, R² or R³ being a halogen and/or at least one R being a halogen; and

n is an integer of 0 to 5.

The composition for the second retardation layer may further include a halogen-free styrene polymer, for example, polystyrene.

The composition for the second retardation layer may further include additives. The additives serve to adjust the wavelength dispersion. Additives having an aromatic fused ring may include 2-naphthylbenzoate, anthracene, phenanthrene, 2,6-naphthalenedicarboxylic acid diester, and/or the like. The additives having an aromatic fused ring may be present in an amount of 0.1 wt % to 30 wt %, for example, 1 wt % to 10 wt %, in the composition for the second retardation layer. Within these ranges, the composition for the second retardation layer can control retardation (e.g., retardation expression) and wavelength dispersion.

The composition for the second retardation layer may further include suitable additives (e.g., known to those skilled in the art). The additives may include pigments, antioxidants, antistatic agents, heat stabilizers, and/or the like, without being limited thereto.

The second retardation layer may be a cured product of the composition, for example, a thermoset or photo-cured product of the composition. The second retardation layer may be a cured coating layer of the composition by heat or light curing and may be formed by any suitable method (e.g., known to those skilled in the art).

The retardation layer stack may have an out-of-plane retardation of −40 nm to less than 0 nm at a wavelength of 550 nm and may satisfy Equation 4. As a result, the retardation layer stack can facilitate improvement in front contrast and can reduce light leakage and color variation at a lateral side while securing good clarity and good viewing angle on a black screen.

$$1.1 \leq R t h ( 4 \; 50 ) / Rt h ( 550 ) \leq 1.5 , \qquad ( 4 )$$

where Rth(450) and Rth(550) are out-of-plane retardations (in nm) of the retardation layer stack at wavelengths of 450 nm and 550 nm, respectively.

In an embodiment, the retardation layer stack has an Rth(550) of −25 nm to −5 nm, −25 nm to −10 nm, or −20 nm to −10 nm.

In an embodiment, in Relation 4, Rth(450)/Rth(550) is from 1.15 to 1.5, for example, 1.2 to 1.4.

In one or more embodiments, similar to Rth(550), Rth(450) may be a negative value. For example, Rth(450) may be from −20 to −5 nm, or from −12 to −7 nm. Within these ranges, the retardation layer stack can satisfy (e.g., easily achieve) Relation 1.

The retardation layer stack may further satisfy Relation 5. As a result, the retardation layer stack can facilitate improvement in front contrast and can reduce light leakage and color variation at a lateral side while securing good clarity and good viewing angle on a black screen.

$$0.1 \leq Rth ( 6 \; 50 ) / Rt h ( 550 ) \leq 1. , \qquad ( 5 )$$

where Rth(650) and Rth(550) are out-of-plane retardations (in nm) of the retardation layer stack at wavelengths of 650 nm and 550 nm, respectively.

In an embodiment, in Formula 5, Rth(650)/Rth(550) may be from 0.2 to 1.0, for example, from 0.5 to 0.9.

In one or more embodiments, similar to Rth(550), Rth(650) may be a negative value. For example, Rth(650) may be from −20 to −1 nm, or from −13 to −5 nm. Within these ranges, the retardation layer stack can (e.g., easily) achieve Relation 2.

In one or more embodiments, the retardation layer stack may satisfy Equation 6 and Equation 7. As a result, the effects of the present disclosure can be achieved (e.g., easily achieved).

$$R t h ( 4 \; 50 ) / Rt h ( 550 ) > Re ( 450 ) / Re ( 550 ) , \qquad ( 6 )$$

$$Re ( 650 ) / Re ( 550 ) > R t h ( 6 \; 50 ) / Rt h ( 550 ) , \qquad ( 7 )$$

where Re(450), Re(550), and Re(650) are in-plane retardations (unit: nm) of the retardation layer stack at wavelengths of 450 nm, 550 nm, and 650 nm, respectively; and

Rth(450), Rth(550), and Rth(650) are out-of-plane retardations (unit: nm) of the retardation layer stack at wavelengths of 450 nm, 550 nm, and 650 nm, respectively.

In one or more embodiments, the retardation layer stack may have a positive wavelength dispersion and may satisfy relations: 1<Re(450)/Re(550)≤1.1 and 0.9≤Re(650)/Re(550)<1.

For example, Re(450)/Re(550) may be from 1.001 to 1.05 and Re(650)/Re(550) may be from 0.9 to 0.99.

The retardation layer stack may have a thickness of 45 μm to 90 μm, for example, 40 μm to 85 μm, or 40 μm to 80 μm. Within these ranges, the retardation layer stack can be used in a polarizing plate.

### Polarizer

The polarizer serves to reduce color reflection and reflectivity over the entire viewing angle by linearly polarizing external light or light incident from the retardation layer stack.

The polarizer may have a degree of polarization of 99% or more and a single light transmittance (Ts) of 42% or more. By concurrently (e.g., simultaneously) satisfying the degree of polarization and the single light transmittance, the polarizer can significantly reduce reflectivity if (e.g., when) stacked on the retardation layer stack. The “single light transmittance” refers to single light transmittance (Ts) measured in the visible region, for example, at a wavelength of 400 nm to 700 nm, and may be measured by a suitable method (e.g., known to those skilled in the art). The “degree of polarization” may be measured by any suitable method (e.g., known in the art). For example, the polarizer may have a degree of polarization of 99% to 99.9999% and a single light transmittance of 42% to 50%.

The light absorption axis of the polarizer may be a stretching direction of a polyvinyl alcohol film in manufacture of the polarizer using the polyvinyl alcohol film, for example, the machine direction (MD) of the polarizer. The polarizer may include a polyvinyl alcohol-based polarizer manufactured by uniaxial stretching of the polyvinyl alcohol film. In one or more embodiments, the polarizer may be manufactured by dyeing, stretching, cross-linking, and color correction of the polyvinyl alcohol film. A polarizer having both the degree of polarization and the light transmittance described above can be realized by suitably changing conditions for the dyeing, stretching, cross-linking, and color correction processes. The polarizer may have a thickness of 5 μm to 40 μm. Within this range, the polarizer can be used in a polarizing plate.

The polarizing plate may further include at least one protective layer described below in addition to the retardation layer stack.

In one or more embodiments, the protective layer may be stacked on the other surface of the polarizer.

### Protective Layer

The protective layer may be stacked on an upper surface of the polarizer to protect the polarizer. The protective layer can protect the polarizer to improve reliability and mechanical strength of the polarizing plate. The protective layer may be stacked in a single layer or multiple layers on the upper surface of the polarizer. The protective layer can be omitted so long as the mechanical properties of the polarizing plate can be secured without the protective layer.

The protective layer may include at least one of an optically transparent protective film or protective coating layer. The protective film may include a film formed of at least one resin selected from among cellulose ester resins including triacetylcellulose (TAC) and/or the like, cyclic polyolefin resins, such as cyclic polyolefin (COP) and/or the like, polycarbonate resins, polyester resins, such as polyethylene terephthalate (PET) and/or the like, polyether sulfone resins, polysulfone resins, polyamide resins, polyimide resins, non-cyclic polyolefin resins, poly (meth)acrylate resins including poly (methyl methacrylate) resins and/or the like, polyvinyl alcohol resins, polyvinyl chloride resins, and polyvinylidene chloride resins, without being limited thereto.

The protective coating layer may be formed of an actinic radiation curable resin composition including an actinic radiation curable compound and a polymerization initiator. The actinic radiation curable compound may include at least one selected from among a cationic polymerizable curable compound, a radical polymerizable curable compound, a urethane resin, and a silicone resin.

The protective layer may be a zero-retardation film or have an in-plane retardation in a set or predetermined range. For example, the protective layer may have an in-plane retardation of less than 5,000 nm, or 5,000 nm or more, 120 nm to 160 nm, or 5 nm to 0 nm, at a wavelength of 550 nm. Within these ranges, the protective layer can protect the polarizing plate without impairing the effects of the retardation layer stack.

The protective layer may have a thickness of 10 μm or less, 5 μm to 300 μm, 5 μm or less, or 5 μm to 200 μm. Within these ranges, the protective layer can be used in a polarizing plate.

A functional coating layer may be further formed on an upper surface of the protective layer. The functional coating layer may include at least one selected from among a hard coating layer, an anti-fingerprint layer, an anti-reflection layer, an anti-glare layer, a low-reflectivity layer, and an ultra-low reflectivity layer.

In one or more embodiments, the protective layer has a low moisture permeability to further improve durability of the polarizing plate after being subjected to high temperature and humidity conditions. For example, the protective layer may have a moisture permeability of 100 g/m²/day or less, for example, 1 g/m²/day to 100 g/m²/day. Within these ranges, the polarizing plate can exhibit good durability and the protective layer can be (e.g., easily) manufactured.

At least one of a protective layer, an adhesive layer, or a bonding layer may be further disposed between the polarizer and the retardation layer stack and/or on a lower surface of the retardation layer stack.

The protective layer is substantially the same as described above.

Herein, the protective layer stacked on the upper surface of the polarizer may be referred to as a first protective layer, the protective layer interposed between the polarizer and the retardation layer stack may be referred to as a second protective layer, and a protective layer stacked on a lower surface of the retardation layer stack may be referred to as a third protective layer.

A second adhesive layer may be further disposed between the polarizer and the retardation layer stack. The second adhesive layer may attach the retardation layer stack to the polarizer. Alternatively, the second adhesive layer may attach the protective layer stacked on the polarizer to the retardation layer stack.

The second adhesive layer may be an adhesive layer having a modulus at 25° C. lower than that of the first adhesive layer. By stacking the second adhesive layer having a lower modulus at 25° C. on an upper surface of the second retardation layer while stacking the first adhesive layer having a relatively higher modulus at 25° C. on a lower surface of the second retardation layer, the polarizing plate can further improve impact resistance if (e.g., when) external impact is applied to the polarizing plate.

A third adhesive layer may be further stacked on the lower surface of the retardation layer stack. The third adhesive layer may attach the polarizing plate to a panel.

Each of the second adhesive layer and the third adhesive layer may be formed of a composition including at least one adhesive resin selected from among a (meth)acrylic resin, an epoxy resin, an epoxy (meth)acrylic resin, a urethane resin, a urethane (meth)acrylic resin, and a silicone resin. For example, the second adhesive layer and the third adhesive layer may include at least one of a thermoset product of the composition or a photo-cured product of the composition.

Each of the second adhesive layer and the third adhesive layer may be a pressure sensitive adhesive layer. Each of a composition for the second adhesive layer and a composition for the third adhesive layer may include the (meth)acrylic resin as described above. The compositions may further include a curing agent. The composition may further include additives.

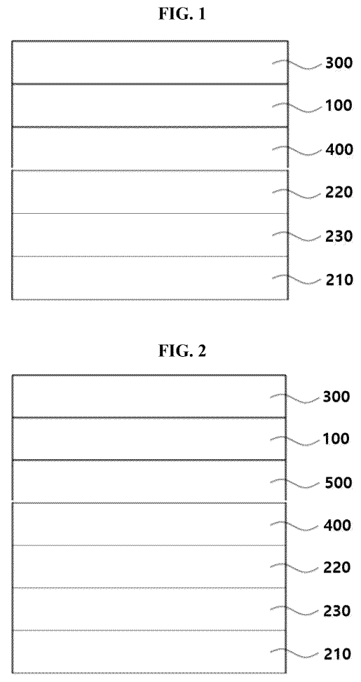

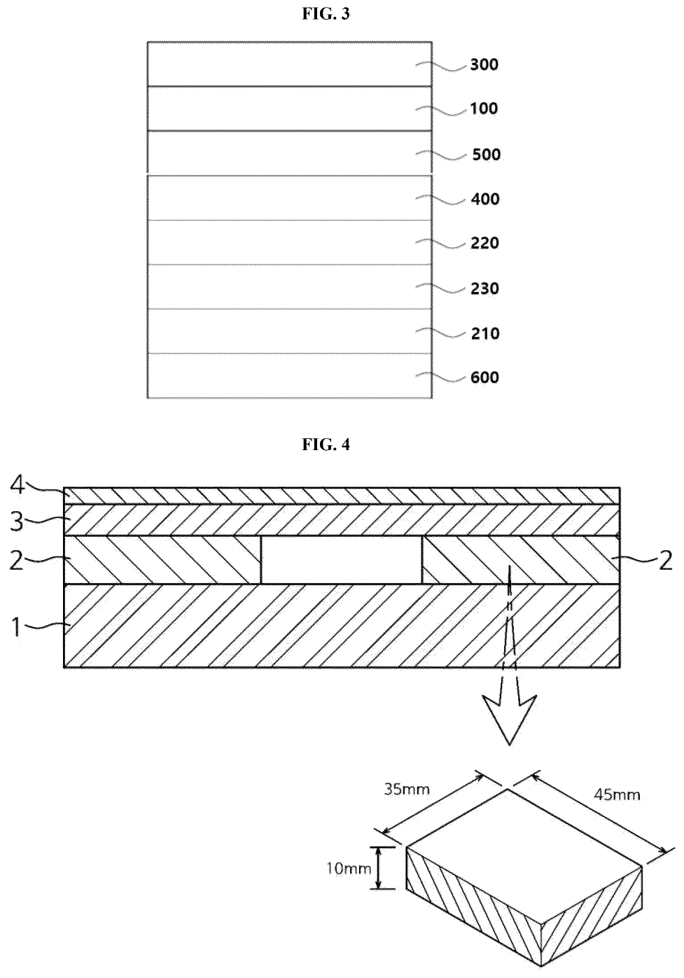

FIGS. 1 to 3 are cross-sectional views of polarizing plates according to embodiments of the present disclosure. In FIGS. 1 to 3, an “upper surface” of the polarizer refers to a light exit surface of the polarizer and a “lower surface” of the polarizer refers to a light incidence surface of the polarizer.

A polarizing plate according to one or more embodiments may include a polarizer 100, a first protective layer 300 formed on an upper surface of the polarizer 100, and a second adhesive layer 400 and a retardation layer stack sequentially stacked on a lower surface of the polarizer 100, in which the retardation layer stack may include a second retardation layer 220, a first adhesive layer 230, and a first retardation layer 210 sequentially stacked from the polarizer 100.

A polarizing plate according to another embodiment may include a polarizer 100, a first protective layer 300 formed on an upper surface of the polarizer 100, and a second protective layer 500, a second adhesive layer 400, and a retardation layer stack sequentially stacked on a lower surface of the polarizer 100, wherein the retardation layer stack may include a second retardation layer 220, an adhesive layer 230, and a first retardation layer 210 sequentially stacked from the polarizer 100.

A polarizing plate according to a further embodiment includes a polarizer 100, a first protective layer 300 formed on an upper surface of the polarizer 100, and a second protective layer 500, a second adhesive layer 400, a retardation layer stack, and a third adhesive layer 600 sequentially stacked on a lower surface of the polarizer 100, wherein the retardation layer stack may include a second retardation layer 220, a first adhesive layer 230, and a first retardation layer 210 sequentially stacked from the polarizer 100.

### Optical Display Apparatus

According to one or more embodiments, the optical display apparatus includes the polarizing plate. The optical display apparatus may include a liquid crystal display. The polarizing plate may be included as a viewer-side polarizing plate of the optical display apparatus. In one or more embodiments, the liquid crystal display may be an IPS or FFS mode liquid crystal display.

The liquid crystal display may include a liquid crystal panel, a viewer-side polarizing plate disposed on one surface of the liquid crystal panel, and a light source-side polarizing plate disposed on the other surface (e.g., facing away from the one surface) of the liquid crystal panel. The light absorption axis of the polarizer of the viewer-side polarizing plate may be substantially orthogonal to the light absorption axis of the light source-side polarizing plate.

In one or more embodiments, a liquid crystal display may include a liquid crystal panel, a viewer-side polarizing plate disposed on one surface of the liquid crystal panel, and a light-side polarizing plate disposed on the other surface (e.g., facing or facing away from the one surface) of the liquid crystal panel. The viewer-side polarizing plate may include a first retardation layer, a second retardation layer, a polarizer, and a protective layer sequentially stacked from the liquid crystal panel. The light source side polarizing plate may include a protective layer, a polarizer, and a protective layer sequentially stacked from the liquid crystal panel. Here, the light absorption axis (e.g., 0°) of the polarizer of the viewer-side polarizing plate is substantially parallel to the slow axis (e.g., 0°) of the first retardation layer. The light absorption axis of the polarizer of the viewer-side polarizing plate is substantially orthogonal to a liquid crystal alignment direction of the liquid crystal panel (e.g., 90°) and a light absorption axis of the polarizer of the light source-side polarizing plate (e.g., 90°), respectively.

In one or more embodiments, the liquid crystal display may include a liquid crystal panel, a viewer-side polarizing plate disposed on one surface of the liquid crystal panel, and a light source-side polarizing plate disposed on the other surface (e.g., facing or facing away from the one surface) of the liquid crystal panel. The light source-side polarizing plate may include a first retardation layer, a second retardation layer, a polarizer, and a protective layer sequentially stacked from the liquid crystal panel. The viewer-side polarizing plate may include a protective layer, a polarizer, and a protective layer sequentially stacked from the liquid crystal panel. Here, the light absorption axis (e.g., 0°) of the polarizer of the light source-side polarizing plate is substantially parallel to the slow axis (e.g., 0°) of the first retardation layer. The light absorption axis of the polarizer of the light source-side polarizing plate is substantially orthogonal to the liquid crystal alignment direction of the liquid crystal panel (e.g., 90°) and the light absorption axis of the polarizer of the viewer-side polarizing plate (e.g., 90°), respectively.

Next, the present disclosure will be described in more detail with reference to some examples. However, it should be noted that these examples are provided for illustration only and are not to be construed in any way as limiting the present disclosure.

### EXAMPLE 1

A polarizer (light transmittance: 44%, thickness: 10 μm) was prepared by dyeing a polyvinyl alcohol film (pre-stretching thickness: 60 μm, Kuraray, Japan) in an aqueous solution of iodine at 55° C., followed by uniaxially stretching the polyvinyl alcohol film to six times its initial length in the MD of the film.

A first retardation layer (+A layer, Re: positive wavelength dispersion, thickness: 45 μm) was prepared by stretching a cyclic olefin polymer (COP) film (ZF, Zeon) to 2.3 times its initial length at 140° C. in the MD of the film.

A second retardation layer (non-liquid crystal layer, +C layer, thickness: 3 μm, Tg: 140° C., moisture permeability: 30 g/m²/day) was prepared by dissolving a fluorine-substituted polystyrene copolymer-containing composition (VM, Eastman) in methyl ethyl ketone, coating the resulting mixture on one surface of a release PET film, drying the composition, and removing the release PET film.

A retardation layer stack of a first retardation layer/first adhesive layer/second retardation layer was prepared by bonding the second retardation layer to an upper surface of the first retardation layer via the first adhesive layer.

A polyethylene terephthalate (PET) film (DSG, DNP) was stacked as a first protective layer on an upper surface of the polarizer and a cyclic olefin polymer (COP) film (ZF, Zeon) was stacked as a second protective layer on a lower surface of the polarizer. Then, the +C layer of the retardation layer stack was stacked on a lower surface of the cyclic olefin polymer (COP) film via a second adhesive layer, thereby preparing a polarizing plate including a stack structure of the PET film/polarizer/COP film/second adhesive layer/second retardation layer/first adhesive layer/first retardation layer. The slow axis of the first retardation layer was tilted at an angle of 0.1° to the light absorption axis of the polarizer (MD of the polarizer).

The first adhesive layer was formed of a composition prepared by adding a solvent to a mixture including 100 parts by weight of an acrylic resin solution (SZ7523, ethyl acetate solution containing an acrylic acid ester copolymer), 3.1 parts by weight of BXX-4805 (toluene and methyl ethyl ketone solution containing a metal acetyl acetonate complex salt) and 14.5 parts by weight of BXX-6460 (toluene diisocyanate-containing acetic ethyl solution) as curing agent solutions, and 0.08 parts by weight of BXX-6342 (containing 98 wt % of a silane compound) as an additive. The acrylic resin solution includes, in terms of solid content, 100 parts by weight of an acrylic resin, 0.31 parts by weight of a metal acetyl acetonate complex salt, 1.45 parts by weight of toluene diisocyanate, and 0.0784 parts by weight of a silane compound. The first adhesive layer was formed by depositing the composition to a set or predetermined thickness on a release film, heat treating the composition at 30° C. for 3 hours, and peeling a resulting film off the release film, and had a thickness of 6.5 μm.

The second adhesive layer was a (meth)acrylic adhesive film having a lower storage modulus at 25° C. than the first adhesive layer.

### Examples 2 to 4

Polarizing plates were prepared in substantially the same manner as in Example 1 except that the thickness of the first adhesive layer and the content (e.g., amount) of each component in the composition for the first adhesive layer were changed to change the modulus of the first adhesive layer.

### Comparative Examples 1 to 4

Polarizing plates were prepared in substantially the same manner as in Example 1 except that the thickness of the first adhesive layer and the content (e.g., amount) of each component in the composition for the first adhesive layer were changed to change the modulus of the first adhesive layer.

### Reference Example 1

A first retardation layer (+A layer, Re: positive wavelength dispersion, thickness: 45 μm) was prepared by stretching a cyclic olefin polymer (COP) film (ZF, Zeon) to 2.3 times an initial length thereof at 140° C. in the MD of the film.

A retardation layer stack including a second retardation layer (non-liquid crystal layer, +C layer, thickness: 4 μm, Tg: 140° C., moisture permeability: 30 g/m²/day) formed on one surface of the first retardation layer was prepared by dissolving a fluorine-substituted polystyrene copolymer-containing composition (VM, Eastman) in methyl ethyl ketone, and coating the composition on one surface of the first retardation layer, followed by drying.

A polarizing plate including a stack structure of the PET film/polarizer/COP film/second adhesive layer/second retardation layer/first retardation layer was manufactured using the retardation layer stack in the same manner as in Example 1.

Retardation of each of the retardation layer stack, the first retardation layer, and the second retardation layer was measured using an Axoscan (Axometry).

(1) Durability at high temperature and high humidity (unit: none): A specimen was prepared by cutting each of the polarizing plates to a size of 10 cm×10 cm (length×width). The specimens were stored in a chamber at 60° C. and 90% RH for 250 hours, and then evaluated as to whether the first retardation layer and the second retardation layer were delaminated if (e.g., when) the first retardation layer and the second retardation layer were pulled by hand.

⊚: No delamination of the first and second retardation layers.

◯: Delamination of the first and second retardation layers required significant force.

Δ: Delamination of the first and second retardation layers required slight force.

x: Very easy delamination of the first and second retardation layers.

(2) Impact resistance (unit: cm): Impact resistance was evaluated by ball drop. For example, the polarizing plate was cut into a polarizing plate specimen having a size of 200 mm×35 mm (length×width) to prepare a specimen for impact resistance evaluation having a cross-section shown in FIG. 4. Referring to FIG. 4, the specimen was prepared by placing two second support 2 (width×length×thickness=45 mm×35 mm×10 mm) on a first support 1 to be spaced apart from each other, stacking a soda lime glass 3 (width×length×thickness=200 mm×35 mm×1.2 cm) on the second supports 2, and stacking a cut polarizing plate specimen 4 over the soda lime glass 3.

Referring to FIG. 4, a ball (spherical shape, cross-sectional diameter: 2 mm, weight: 44 g) was dropped vertically from a set or predetermined height onto an upper surface of the cut polarizing plate specimen 4 at the front center. The ball was dropped with a vertical drop distance of the ball increasing from 150 mm, to 200 mm, and to 250 mm sequentially. The cut polarizing plate specimen and the soda lime glass were observed with the naked eye and evaluated according to the following criteria. The presence of cracks and/or fracture was evaluated with the naked eye.

⊚: Absence of cracks and fracture in the +C layer of the cut polarizing plate specimen.

◯: Slight cracks and fracture in the +C layer in the +C layer of the cut polarizing plate specimen, which were very difficult to identify with the naked eye.

Δ: Cracks and fracture in the +C layer of the cut polarizing plate specimen, which were visible with the naked eye.

x: Cracks and fracture in the +C layer of the cut polarizing plate specimen, which were easily visible with the naked eye.

(3) Bending: Each of the polarizing plates was cut to a size of 10 cm×10 cm (length×width) and bent to have a radius of curvature of 2 mm such that the retardation layer stack side of the polarizing plate was on the outside. No cracks and/or lifting of the retardation layer stack was rated as ◯ and any cracks and/or lifting was rated as x.

(4) Color variation (unit: none): The polarizing plate of each of Examples and Comparative Examples was used instead of a viewer-side polarizing plate in a 55-inch TV and the TV was operated (e.g., on). A color coordinate distance between color coordinates (60°, 45°) and (60°, 135°) in the color coordinate system (x, y) was measured. A lower color coordinate distance indicates a lower color variation at a lateral side.

TABLE 1

| | | Example | | | |
|---|---|---|---|---|---|
| | | 1 | 2 | 3 | 4 |
| +C layer | Thickness | 3 | 3 | 3 | 3 |
| | (μm) | | | | |
| First | Thickness | 6.5 | 8.5 | 9 | 4.5 |
| adhesive | (μm) | | | | |
| layer | Modulus | 6 × 10⁵ | 8 × 10⁵ | 7 × 10⁵ | 4 × 10⁵ |
| | (Pa) | | | | |

| | | | | |
|---|---|---|---|---|
| Value of Equation 1 | 0.46 | 0.35 | 0.33 | 0.67 |
| Durability at high | ⊚ | ⊚ | ⊚ | ⊚ |
| temperature/humidity | | | | |
| Impact resistance | ⊚ | ◯ | ◯ | ⊚ |
| Bending properties | ◯ | ◯ | ◯ | ◯ |
| Color variation | Good | Good | Good | Good |

TABLE 2

| | | | | | | | Reference |
|---|---|---|---|---|---|---|---|
| | | Comparative Example | | | | | Example |
| | | 1 | 2 | 3 | 4 | 5 | 1 |
| +C layer | Thickness | 3 | 3 | 3 | 3 | 3 | 3 |
| | (μm) | | | | | | |
| First | Thickness | 13 | 6.5 | 13 | 13 | 2.3 | — |
| adhesive | (μm) | | | | | | |
| layer | Modulus | 8 × 10⁵ | 2 × 10⁴ | 4 × 10⁴ | 3 × 10⁶ | 3 × 10⁵ | — |
| | (Pa) | | | | | | |

| | | | | | | |
|---|---|---|---|---|---|---|
| Value of Equation 1 | 0.23 | 0.46 | 0.23 | 0.23 | 1.30 | — |
| Durability at high | ⊚ | ◯ | ◯ | Δ | ⊚ | ⊚ |
| temperature/ | | | | | | |
| humidity | | | | | | |
| Impact resistance | X | X | X | X | X | ⊚ |
| Bending properties | ◯ | ◯ | ◯ | ◯ | ◯ | X |
| Color variation | Good | Good | Good | Good | Good | Good |

As shown in Table 1, the polarizing plates of the present disclosure had good durability and reliability after being left at high temperature/humidity or at high temperature for a long period of time, good impact resistance and bending properties, good front contrast ratio, low brightness in black mode to reduce light leakage and color variation at a lateral side.

As shown in Table 2, the polarizing plates of Comparative Examples failed to achieve all of the advantageous or desirable effects of the present disclosure.

As used herein, the terms “use,” “using,” and “used” may be considered synonymous with the terms “utilize,” “utilizing,” and “utilized,” respectively. As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The use of “may” when describing embodiments of the inventive concept refers to “one or more embodiments of the inventive concept.”

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Here, unless otherwise defined, the listing of steps, tasks, or acts in a particular order should not necessarily means that the invention or claims require that particular order. That is, the general rule that unless the steps, tasks, or acts of a method (e.g., a method claim) actually recite an order, the steps, tasks, or acts should not be construed to require one.

It should be understood that various modifications, changes, alterations, and equivalent embodiments may be made by those skilled in the art without departing from the spirit and scope of the appended claims, and equivalents therefore.

What is claimed is:

1. A polarizing plate comprising:
a polarizer having a first surface and a second surface facing the first surface; and
a retardation layer stack on the first surface of the polarizer,
wherein the retardation layer stack comprises a second retardation layer, a first adhesive layer, and a first retardation layer sequentially stacked from the first surface of the polarizer,
a storage modulus of the first adhesive layer at 25° C. is 1×10⁵ Pa to 1×10⁶ Pa, and
the second retardation layer and the first adhesive layer satisfy Relation 1:
$$0.3 \leq T 2 / T 1 \leq 1.$$
where T1 is a thickness of the first adhesive layer in unit of μm, and
T2 is a thickness of the second retardation layer in unit of μm.

2. The polarizing plate as claimed in claim 1, wherein the first adhesive layer has a thickness of 13 μm or less.

3. The polarizing plate as claimed in claim 1, wherein the second retardation layer has a thickness of 10 μm or less.

4. The polarizing plate as claimed in claim 1, wherein a storage modulus of the first adhesive layer at 60° C. is 6×10⁴ Pa to 8×10⁵ Pa.

5. The polarizing plate as claimed in claim 1, wherein the first adhesive layer has a ratio of the storage modulus at 25° C. to a storage modulus at 60° C. of 1.25:1 to 1.6:1.

6. The polarizing plate as claimed in claim 1, wherein the first adhesive layer has a glass transition temperature of −10° C. or less.

7. The polarizing plate as claimed in claim 1, wherein the first adhesive layer is a pressure sensitive adhesive layer.

8. The polarizing plate as claimed in claim 1, wherein the first adhesive layer comprises a thermal cured product of a composition comprising a (meth)acrylic based resin and a curing agent.

9. The polarizing plate as claimed in claim 8, wherein
the (meth)acrylic based resin comprises a (meth)acrylic copolymer of a monomer mixture, the monomer mixture comprising a (meth)acrylic monomer comprising an alkyl group and a (meth)acrylic monomer comprising a cross-linkable functional group, and
the curing agent comprises at least one selected from among an isocyanate curing agent, a metal chelate curing agent, an aziridine curing agent, an epoxy curing agent, and a carbodiimide curing agent.

10. The polarizing plate as claimed in claim 1, wherein the second retardation layer is a non-liquid crystal layer.

11. The polarizing plate as claimed in claim 10, wherein the second retardation layer comprises at least one of a cellulose based compound or a polystyrene based compound as a main component.

12. The polarizing plate as claimed in claim 11, wherein each of the cellulose based compound and the polystyrene based compound comprises a halogen.

13. The polarizing plate as claimed in claim 1, wherein the first retardation layer is a hydrophobic non-liquid crystalline film.

14. The polarizing plate as claimed in claim 13, wherein the first retardation layer comprises a cyclic olefin polymer (COP) film or a cyclic olefin polymer (COC) film.

15. The polarizing plate as claimed in claim 1, wherein the first adhesive layer is directly on each of the first retardation layer and the second retardation layer.

16. The polarizing plate as claimed in claim 1, wherein the first retardation layer is a +A layer and the second retardation layer is a +C layer.

17. The polarizing plate as claimed in claim 1, further comprising a first protective layer on the second surface of the polarizer, and the first protective layer having a moisture permeability of 100 g/m²/day or less.

18. The polarizing plate as claimed in claim 1, further comprising a second adhesive layer between the retardation layer stack and the polarizer.

19. The polarizing plate as claimed in claim 18, wherein a storage modulus of the second adhesive layer at 25° C. is lower than the storage modulus of the first adhesive layer at 25° C.

20. An optical display apparatus comprising the polarizing plate as claimed in claim 1.
